(19) United States
(12) Patent Application Publication
(10) Pub. No.: US 2014/0369901 A1
(43) Pub. Date: Dec. 18, 2014

(54) Flexible Microreactors

(71) Applicant: John C. Warner, Wilmington, MA (US)

(72) Inventor: John C. Warner, Wilmington, MA (US)

(21) Appl. No.: 13/921,099

(22) Filed: Jun. 18, 2013

(51) Int. Cl. B29C 67/00; G03F 7/20; B01J 19/00

(52) U.S. Cl. CPC B29C 67/0062; B01J 19/0093; G03F 7/20; B29C 67/0085; B29K 2901/12; B29L 2031/756
USPC 422/502; 156/291; 156/273.3; 156/277; 156/242; 427/177; 430/8

(57) ABSTRACT

The present application for patent is in the field of microreactors and more specifically in the field of microreactors which are prepared from flexible substrates. Methods of preparing flexible substrates using various printing methods are also disclosed.

### FIELD OF THE INVENTION

The present application for patent is in the field of microreactors and more specifically in the field of microreactors which are prepared from flexible substrates. Methods of preparing flexible substrates using various printing methods are also disclosed.

### BACKGROUND

Microreactors are being used for a number of purposes including chemical reactions, process optimization, statistical design of experimentation, combinatorial chemistry, analyses, separations and pollution control. And there are a plethora of advantages to using microreactors such as reduction of waste, enhanced efficiency of mixing, better control of contact time, reaction time and temperature, better screening of potential reactants, continuous multistep synthesis, integrated separation techniques, solid state chemistry, such as catalytic and solid state peptide synthesis, safe handling of toxic materials, safe handling of highly energetic reactions, improved nanosynthesis such as quantum dot synthesis and separations to name a few.

Microreactors offer many advantages over conventional scale reactors, including vast improvements in energy efficiency, reaction speed and yield, safety, reliability, scalability, on-site/on-demand production, and a much finer degree of process control.

Microreactors can range from a few inlet/outlets ports and one channel to many ports and an elaborate array of channels. The channels may be situated in one straight line or continued back and forth across a substrate. Often the channels are configured to contain chamber-like features along their length along with a multitude of intersections with other channels. Depending onto the desired process there may be a number of microreactors connected to each other either in series or in parallel.

One limitation of the currently available microreactors is that they are made of hard, inflexible materials. The microchannels are generally provided in a solid substrate and then covered with either a solid or a flexible cover sheet. Microreactor substrates are generally fabricated from glass panels, ceramic substrates or silicon wafers which have channel designs etched into them. Hard plastic substrates can be used where the channel designs are created by being molded into the plastic.

Another limitation is that the designs and layouts of current microreactors, once created, can not be changed. So if it is found that a different arrangement of channels will provide a more optimum result, a new microreactor needs to be prepared by etching or molding. Microreactors are generally reused due to the expense of making them and the materials they are made therefrom. Due to their rigidity, microreactors are always planar and either are stand alone devices or only fit into areas specifically designed for planar devices. Microreactors are a one process set-up, i.e. if more than one reaction or process is required, then more than one microreactor is required and the processes are generally set up in a serial fashion.

Microreactors would be more readily employed and easier to use if they could be made flexible, inexpensively, easily manufacturable, light weight, and readily changeable.

Thus there is a need for microreactors with these characteristics.

### BRIEF DESCRIPTION OF THE DRAWINGS

FIG. 1 depicts a simple microreactor showing a flexible substrate 10, microchannels 12, 2 inlet ports 14, the area where the 2 inlet ports converge 16 and an exit port 18.

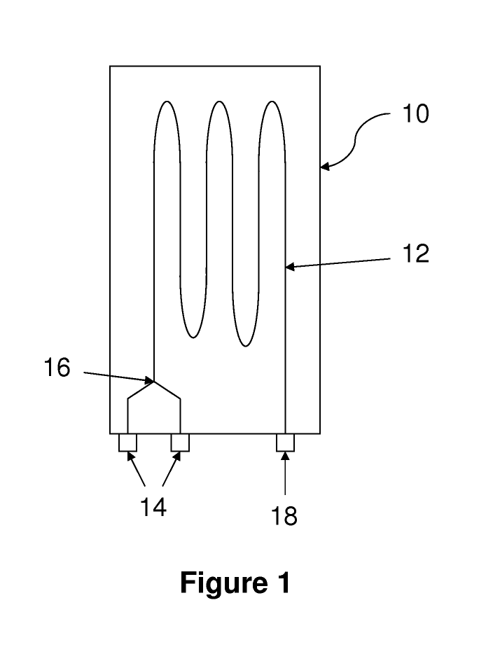

FIG. 2 depicts a method for preparing a microreactor of the present disclosure showing a flexible substrate 20, upon which an inkjet printer 22, is depositing selected materials 24, to create channels 26 and 28. Also shown is a cover sheet, 29.

### DETAILED DESCRIPTION OF THE DISCLOSURE

This disclosure introduces a solution to the problem of providing microreactors that are flexible, inexpensive, easily manufacturable, light weight, and readily changeable. Virtually all microreactors are static/passive in that they function as fixed chambers and can be visualized as an elaborate test tube in which reagents are mixed and/or allowed to react with time and temperature or other reaction variables being applied.

As used herein, the conjunction “and” is intended to be inclusive and the conjunction “or” is not intended to be exclusive unless otherwise indicated. For example, the phrase “or, alternatively” is intended to be exclusive.

The use of the terms “a” and “an” and “the” and similar referents in the context of describing the invention (especially in the context of the claims) are to be construed to cover both the singular and the plural, unless otherwise indicated herein or clearly contradicted by context.

The terms “comprising,” “having,” “including,” and “containing” are to be construed as open-ended terms (i.e., meaning “including, but not limited to,”) unless otherwise noted.

As used herein the term microreactor includes microfluidic technologies, flow reactors, flow chambers, microstructured reactors, and microchannel reactors as well as other terminologies that are used to describe the foregoing.

In a first embodiment are methods for selectively depositing material onto flexible substrates to form channels on the substrate followed by providing a top cover to enclose the channels.

In a second embodiment are methods for selectively depositing material onto flexible substrates to form channels on the substrate using various printing techniques such as photolithography, lithography, rotogravure, ink jet, stereolithography, electrophoretic methods, or letterpress followed by providing a top cover to enclose the channels.

In a third embodiment are methods for selectively depositing material onto flexible substrates to form channels on the substrate using various printing techniques such as photolithography, lithography, rotogravure, ink jet, stereolithography, electrophoretic methods, or letterpress in which the materials are deposited using computer guidance followed by providing a top cover to enclose the channels.

In a fourth embodiment are methods for selectively depositing material onto one of the surfaces of a flexible substrates to form channels on the substrate followed by rolling the flexible substrate onto itself wherein the backside surface of the flexible substrate without the deposited material covers the deposited material to enclose the channels formed by the deposited materials thus providing a top cover to enclose the channels.

In a fifth embodiment are methods for selectively depositing material onto flexible substrates to form channels on the substrate using various printing techniques such as photolithography, lithography, rotogravure, ink jet, stereolithography, electrophoretic methods, or letterpress followed by rolling the flexible substrate onto itself wherein the backside surface of the flexible substrate without the deposited material covers the deposited material to enclose the channels formed by the deposited materials thus providing a top cover to enclose the channels.

In a sixth embodiment are methods for selectively depositing material onto flexible substrates to form channels on the substrate using various printing techniques such as photolithography, lithography, rotogravure, ink jet, stereolithography, electrophoretic methods, or letterpress in which the materials are deposited using computer guidance followed by rolling the flexible substrate onto itself wherein the backside surface of the flexible substrate without the deposited material without the deposited material covers the deposited material to enclose the channels formed by the deposited materials providing a top cover to enclose the channels.

In a seventh embodiment are microreactors prepared by any of the methods of the foregoing embodiments.

Flexible substrates useful for the current disclosure include, for example, polymeric films, such as, for example, polyethylene terephthalate, polyolefins such as polyethylene or polypropylene, polystyrene, polycarbonate, polyimide, polyamide, polysulfone, polyvinyl chloride, fluorinated polymer films, cellulose triacetate, cellophane or polyurethane. Other flexible substrates include metal films, flexible silicon wafers or polymer coated papers, including polymer impregnated paper. The flexible substrates are chosen for their ability to form and deform depending on the desired configuration. For example, a substrate may be just flexible enough to form a curve with a radius of 6 inches or it may be flexible enough to roll into a cylinder with a half inch radius with one or more windings either with a discreet cover or a cover provided by the backside of the substrate as described below.

The surfaces of the flexible substrates may be treated to prepare a desired surface for application of the microchannel materials, such as, for example, adhesion promotion, lowering the surface energy, etc. The backside may be treated before or after depositing the microchannel materials, for example with adhesive materials, surface energy alteration materials and the like.

Materials that are selectively deposited on the substrate may be deposited by printing methods. These methods include, for example, ink jet printing, lithography, rotogravure, electrophoretic methods, letterpress and the like. The printing processes may include more than one material and more than one application, so that multiple materials may be deposited to create a desired microreactor, and more than one application may be made to build up a desired microreactor design. For example one material may have an affinity for a reactant such as a catalyst while a second material that is deposited may be inert to the catalyst.

As one example of the current disclosure, in the inkjet printing process, the inks are sequentially deposited until the desired thickness, height and arrangement of the trenches are generated. More than one ink jet head may be used depending on the amount and types of materials to be deposited. The inkjet process may be controlled by a computer interface in which a design is generated using computer software which then directs the inkjet printer to deposit one or more of the selected material onto the substrate. This process provides for the ability to generate a large number of microreactor configurations which allows the researcher to determine the optimum configuration for a particular desired microreactor process without the expense of creating microreactors prepared in the typical manner. The processes of the current disclosure lend themselves to being produced by a process called roll-to-roll printing in which a web of flexible material is continuously fed into a printer which deposits the materials in a desired design and, if necessary, further processed, such as heat or radiation cured, then rolled up at the end of the process, to be later converted into individual microreactor systems.

The deposited materials can be polymeric compositions that contain one or more materials designed for adhesion, surface tension manipulation, and the like. They may be deposited as hot melts or from solvent solutions, either water based or organic solvent based. Polymer compositions may be deposited which can be further cured or hardened by heat and/or electromagnetic radiation.

Other methods of selectively depositing materials include photolithography. In these methods a coating of photolithographic material is applied, either from a solvent, such as water, or an organic solvent, or by using dry film photoresist techniques in which a roll of photoresist, comprising a support layer to which a photolithographic composition has been applied and dried, is applied to the flexible substrate using such techniques as roll lamination In these cases a photomask is positioned on the photolithographic composition and actinic radiation is applied to either harden the photoresist so that it will not dissolve in a specific developer or to convert the photoresist to a material which is soluble in a specific developer, in both cases defining the channels. In either case, after development a portion of the photoresist is removed to leave behind the desired channels. The photoresist process may also be performed using direct write systems in which a beam of light is directed by a computer to expose certain areas of the photoresist to harden or make it soluble in developer. In this manner a design may be first generated on the computer using computer software.

Another method of depositing material onto a substrate employs 3D depositing techniques such as stereolithography wherein the channels are sequentially built up from the bottom of the channel using photo sensitive materials. Again this process is controlled by a computer interface with the design being created using computer software.

The channels formed by the currently disclosed methods can have any of a number of desired shapes including straight lines, curves, s-shaped or combinations thereof, the shapes are limitless.

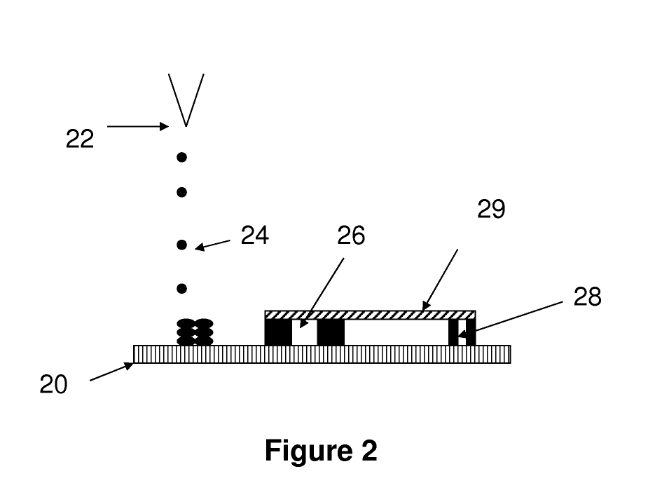

When the materials are deposited, the formed channels have three sides, initially. The deposited materials may form the two lateral sides of the channel with the flexible substrate forming the third or bottom side of the channel. However some of the material may be deposited on the third side as well so that all three sides of the channel are made of the same material. The top cover may be precoated with the same material that is used to make the two lateral sides and/or the third (bottom) side of the channel, or it may be different. In certain embodiments of the current disclosure, more than one material is deposited either as one or both of the lateral sides and/or as the third side of the channel. In a further embodiment a second material may be deposited onto material which was first deposited to allow for various surfaces of the channel to be coated with different materials. The versatility of the current disclosure can be seen in FIG. 2 where a particular channel is fabricated, 26, while a different style or type of channel, 28, is fabricated in the same microreactor.

In other embodiments of the current disclosure, materials that are selectively deposited on the substrate include for example materials that contain reactive groups or different polarities, which allows for manipulation of the surfaces of the channel such as, for example, for DNA or protein sequencing in which various channels will be pretreated to attach desired sequence materials to the surface which then can be transferred to the medium being sent through the microreactor channels. Surfaces may also be deposited with materials which can preferential changed their physical characteristics such as surface energy to either be adherent or non adherent to materials which flow through the channels when in use.

In other embodiments of the current disclosure the channels may be filled by any of a number of materials, such as, for example, media used in chromatography. In this embodiment more than one material may be used to fill individual channels so that, in the case of chromatography, the various media are arranged to allow for selected separations of materials by the different media.

In other embodiments the channels may be fully or partially filled with solid state materials designed for solid state chemistry such as, for example, solid support materials for catalysts.

A top cover is applied to provide for the final side of the channel and enclose it. The top cover is made from a flexible material such as, for example, polymeric films such as, for example the same material as uses as the flexible substrate or different flexible, polymeric films, such as for example, polyethylene terephthalate, polyolefins such as polyethylene or polypropylene, polystyrene, polycarbonate, or polyurethane. Other flexible top covers include metal films, flexible silicon wafers or polymer coated papers, including polymer impregnated paper and other flexible materials as described above.

In other embodiments of the current disclosure, material is deposited onto one of the surfaces of the flexible substrate to create the desired channels and is rolled up onto itself such that the backside surface of the flexible substrate comes into contact with the deposited material, the backside surface functioning as the top cover for the channels. In this manner, a plethora of channels can be fabricated into one microreactor device depending on the geometry of the channels and the number of wraps.

Microreactors of the current disclosure may be of the continuous type or may be batch reactors, the advantage being its small size, which in some embodiments, can fabricate materials at volumes as low as 0.4 picoliters.

Selected materials include inert spacing material which results in a microreactor that has microchannel and/or micro mixing processes. Precursor materials may be deposited that are later treated with materials in an activation step to activate them. This activation step may be a step which removes material to reveal an active component in the deposited material, or may be reacted with a reactant to provide a reactive site on the deposited material. Other selected reactive materials may be deposit onto the surface of the deposited material. The deposited material may be reacted to physically alter the surface, such as for example, removing material to create micro indentations/cavities which may vary in size that allow other material to be captured, such as, for example, size-exclusion chromatography. The bottom of the indentation may be treated to provide differential affinity for materials such as biomaterial.

Rolling the substrate so that the deposited material is outwardly positioned may include rolling around a central, solid core, or other core which may further have functionalities. The substrate is rolled so that the back side of a second winding of the substrate is placed in intimate contact with the outwardly positioned deposited material to create channels and other passages.

In other embodiments more than one winding can occur which allows for three dimensional channeling and/or different functionalities in different concentric layers of the rolled substrate.

What are claimed are:

1) A method of preparing a microreactor comprising:
a) Providing a flexible substrate having a top surface and a bottom surface,
b) Selectively depositing material onto one or both of the surfaces of the substrate to form channels, and
c) Providing a cover to enclose the channels.

2) The method of claim 1, wherein the selected material is deposited by printing techniques.

3) The method of claim 2, wherein the selected material is deposited using photoresist techniques.

4) The method of claim 2, wherein the selected material is deposited by lithography, rotogravure, ink jet, stereolithography, electrophoretic methods, or letterpress.

5) The method of claim 4, wherein the selected material is deposited in a pattern designed using a computer interface.

6) A method of preparing a microreactor comprising:
a) Providing a flexible substrate having a top surface and a bottom surface,
b) Selectively depositing material onto one of the surfaces of the substrate to form channels, and
c) Rolling the flexible substrate onto itself,
wherein the surface without the deposited material covers the deposited material to enclose the channels formed by the deposited materials.

7) The method of claim 6, wherein the selected material is deposited by printing techniques.

8) The method of claim 7, wherein the selected material is deposited using photoresist techniques.

9) The method of claim 7, wherein the selected material is deposited by lithography, rotogravure, ink jet, stereolithography, electrophoretic methods, or letterpress.

10) The method of claim 9, wherein the selected material is deposited in a pattern designed using a computer interface.

11) A microreactor prepared by a method comprising:
a) Providing a flexible substrate having a top surface and a bottom surface,
b) Selectively depositing material onto one or both of the surfaces of the substrate to form channels, and
c) Providing a cover to enclose the channels.

12) The microreactor of claim 11, wherein the selected material is deposited by printing techniques.

13) The microreactor of claim 12, wherein the selected material is deposited using photoresist techniques.

14) The microreactor of claim 12, wherein the selected material is deposited by lithography, rotogravure, ink jet, stereolithography, electrophoretic methods, or letterpress.

15) The microreactor of claim 14, wherein the selected material is deposited in a pattern designed using a computer interface.

16) A microreactor prepared by a method comprising:
a) Providing a flexible substrate having a top surface and a bottom surface,
b) Selectively depositing material onto one of the surfaces of the substrate to form channels, and
c) Rolling the flexible substrate onto itself,
wherein the surface without the deposited material covers the deposited material to enclose the channels formed by the deposited materials.

17) The microreactor of claim 16, wherein the selected material is deposited by printing techniques.

18) The microreactor of claim 17, wherein the selected material is deposited using photoresist techniques.

19) The microreactor of claim 17, wherein the selected material is deposited by lithography, rotogravure, ink jet, stereolithography, electrophoretic methods, or letterpress.

20) The microreactor of claim 19, wherein the selected material is deposited in a pattern designed using a computer interface.
